(19) United States
(12) Patent Application Publication
(10) Pub. No.: US 2026/0033046 A1
(43) Pub. Date: Jan. 29, 2026

(54) LIGHT-EMITTING DIODE AND LIGHT-EMITTING DEVICE

(71) Applicant: HUBEI SAN'AN OPTOELECTRONICS CO., LTD., Ezhou (CN)

(72) Inventors: CHAO LU, Ezhou (CN); XIONG TU, Ezhou (CN); JIN XU, Ezhou (CN); LING-YUAN HONG, Ezhou (CN); QING WANG, Ezhou (CN); JIANGBIN ZENG, Ezhou (CN)

(21) Appl. No.: 19/280,062

(22) Filed: Jul. 24, 2025

(30) Foreign Application Priority Data
Jul. 26, 2024 (CN) 202411019536.8

(51) Int. Cl. H10H 20/84; H10H 20/831

(52) U.S. Cl. CPC H10H 20/84; H10H 20/831

(57) ABSTRACT

A light-emitting diode includes an epitaxial structure, multiple first contact electrodes and an insulating layer. The epitaxial structure includes a first semiconductor layer, an active layer and a second semiconductor layer sequentially stacked in that order. The multiple first contact electrodes are distributed above the second semiconductor layer and electrically connected to the second semiconductor layer. The insulating layer covers at least a part of each of the multiple first contact electrodes and the epitaxial structure. The insulating layer includes a first through hole exposing a part of a surface of each of the multiple first contact electrodes. A minimum distance between an edge of the first through hole and an edge of each of the multiple first contact electrodes is defined as a first spacing. At least two first contact electrodes have unequal first spacings relative to the first through hole.

### CROSS-REFERENCE TO RELATED APPLICATION

This application claims priority to Chinese patent application No. CN202411019536.8, filed to China National Intellectual Property Administration (CNIPA) on Jul. 26, 2024, which is herein incorporated by reference in its entirety.

### TECHNICAL FIELD

The disclosure relates to the field of semiconductor technologies, and more particularly to a light-emitting diode and a light-emitting device.

### BACKGROUND

Light-emitting diode (LED) is a semiconductor light-emitting element, usually made of semiconductors such as gallium nitride (GaN), gallium arsenide (GaAs), gallium phosphide (GaP), and gallium arsenide phosphide (GaAsP), etc., and its core is a PN junction with light-emitting characteristics. LED has advantages of high luminous intensity, high efficiency, small size, and long service life, which is considered as one of the most promising light sources at present. However, the existing light-emitting diodes still have the problem of poor electrical over-stress (EOS) resistance due to improper design.

### SUMMARY

In order to solve shortcomings of light-emitting diodes in the related art, the disclosure provides a light-emitting diode, which includes an epitaxial structure, multiple first contact electrodes and an insulating layer.

The epitaxial structure includes a first semiconductor layer, an active layer and a second semiconductor layer sequentially stacked in that order. The multiple first contact electrodes are distributed above the second semiconductor layer and electrically connected to the second semiconductor layer. The insulating layer covers at least a part of each of the multiple first contact electrodes and the epitaxial structure. The insulating layer includes a first through hole exposing part of a surface of each of the multiple first contact electrodes. A minimum distance between an edge of the first through hole and an edge of each of the multiple first contact electrodes is defined as a first spacing. At least two of the multiple first contact electrodes have unequal first spacings relative to the first through hole.

The disclosure also provides a light-emitting device, which uses the light-emitting diode described in the above embodiment.

Based on the above, compared with the related art, the light-emitting diode provided by the disclosure is limited by the spacing between the first contact electrode and the first through hole, so that the EOS capability of the light-emitting diode can be effectively improved. This design avoids the risk of structural burnout under overvoltage conditions that may lead to functional failure of the light-emitting diode.

Other features and beneficial effects of the disclosure will be set forth in the description which follows, and in part will be apparent from the description, or may be learned by practice of the disclosure. Objects and other beneficial effects of the disclosure can be realized and obtained by the structure particularly pointed out in the specification, claims and drawings.

### BRIEF DESCRIPTION OF DRAWINGS

In order to more clearly explain embodiments of the disclosure or the technical scheme in the related art, the drawings needed in the description of the embodiments or the related art will be briefly introduced below. Apparently, the drawings in the following description are some embodiments of the disclosure, and other drawings can be obtained according to these drawings without creative work for those skilled in the related art. In the following description, unless otherwise specified, positional relationships described in the attached drawings are based on directions of components in the drawings.

FIG. 1 illustrates a sectional view of a light-emitting diode according to an embodiment of the disclosure.

FIG. 2 illustrates a top view of the light-emitting diode according to the embodiment of the disclosure.

FIG. 3 illustrates a top view of a light-emitting diode according to another embodiment of the disclosure.

FIG. 4 illustrates a partial enlarged view of a portion A in FIG. 4.

FIG. 5 illustrates a top view of a light-emitting diode according to still another embodiment of the disclosure.

FIG. 6 illustrates a sectional view of a light-emitting diode according to even still another embodiment of the disclosure.

FIG. 7 illustrates a sectional view of a light-emitting diode according to further still another embodiment of the disclosure.

### DETAILED DESCRIPTION OF EMBODIMENTS

In order to make objects, technical schemes and advantages of embodiments of the disclosure clearer, the technical schemes in the embodiments of the disclosure will be described clearly and completely with the attached drawings. Apparently, the described embodiments are a part of the embodiments of the disclosure, but not all embodiments. Technical features designed in different embodiments of the disclosure described below can be combined with each other as long as they do not conflict with each other. Based on the embodiments in the disclosure, all other embodiments obtained by those skilled in the related art without creative work belong to the scope of protection of the disclosure.

In order to achieve at least one advantage or other advantages of the disclosure, an embodiment of the disclosure provides a light-emitting diode, which at least includes an epitaxial structure, multiple second contact electrodes and an insulating layer.

The epitaxial structure includes a first semiconductor layer, an active layer and a second semiconductor layer sequentially stacked in that order. The multiple first contact electrodes are distributed above the second semiconductor layer and electrically connected to the second semiconductor layer. The insulating layer covers at least a part of each of the multiple first contact electrodes and the epitaxial structure. The insulating layer includes a first through hole exposing part of a surface of each of the multiple first contact electrodes. A minimum distance between an edge of the first through hole and an edge of each of the multiple first contact electrodes is defined as a first spacing. At least two of the multiple first contact electrodes have unequal first spacings relative to the first through hole. Through the above technical scheme, the EOS capability of the light-emitting diode can be effectively improved.

In an embodiment, the first spacing is in a range of 2-10 micrometers to improve the reliability of the light-emitting diode.

In an embodiment, the first spacing is defined as a distance between a bottom edge of the first through hole and an upper surface edge of each of the multiple first contact electrodes.

In an embodiment, the first spacing includes a first sub-spacing and a second sub-spacing, the first sub-spacing is greater than the second sub-spacing, and the first contact electrode with the second sub-spacing is closer to an edge of the light-emitting diode than the first contact electrode with the first sub-spacing.

In an embodiment, the first spacing includes a first sub-spacing and a second sub-spacing, and the first sub-spacing is greater than the second sub-spacing. The light-emitting diode further includes multiple second contact electrodes spaced apart above the first semiconductor layer and electrically connected to the first semiconductor layer; the multiple first contact electrodes are distributed both between the multiple second contact electrodes and in a periphery of the multiple second contact electrodes; at least one of the multiple first contact electrodes located between adjacent two of the multiple second contact electrodes has the first sub-spacing; and at least one of the multiple first contact electrodes located at the periphery of the multiple second contact electrodes and closest to an edge of the light-emitting diode has the second sub-spacing.

In an embodiment, a difference between the first sub-spacing and the second sub-spacing is in a range of 1 to 5 micrometers to further ensure the photoelectric characteristics.

In an embodiment, the first contact electrode with the second sub-spacing has smaller quantity than that of the first contact electrode with the first sub-spacing.

In an embodiment, cross-sectional areas of the first through hole s respectively corresponding to the multiple first contact electrodes are equal on a same horizontal plane, and cross-sectional areas of at least two of the multiple first contact electrodes are unequal on the same horizontal plane.

In an embodiment, on the same horizontal plane, a first contact electrode of the at least two of the multiple first contact electrodes with a smaller cross-sectional area is closer to an edge of the light-emitting diode than another first contact electrode of the at least two of the multiple first contact electrodes with a larger cross-sectional area.

In an embodiment, the multiple first contact electrodes have diameters, and the diameters of at least two of the multiple first contact electrodes are unequal.

In an embodiment, the diameters of the multiple first contact electrodes include a first diameter and a second diameter, the first diameter is larger than the second diameter, and the first contact electrode with the second diameter is closer to an edge of the light-emitting diode than the first contact electrode with the first diameter; the first diameter is in a range of 18 to 30 micrometers, and the second diameter is in a range of 15 to 25 micrometers.

By limiting the size of the first spacing and the first contact electrodes in the above embodiments, the balance between current distribution and luminous brightness in the light-emitting diode can be effectively regulated and controlled, and the EOS capability of the light-emitting diode can be improved.

In an embodiment, the light-emitting diode further includes multiple current blocking layers respectively located below the multiple first contact electrodes; wherein an orthographic projection of each of the multiple first contact electrodes on the epitaxial structure is within a range of an orthographic projection of each of the multiple current blocking layers on the epitaxial structure; a minimum distance between the first through hole located above each of the multiple first contact electrodes and an edge of each of the multiple current blocking layers located below each of the multiple first contact electrodes is defined as a second spacing; and second spacings correspondingly to at least two of the multiple first contact electrodes are unequal.

In an embodiment, the second spacing is in a range of 5 to 15 micrometers.

In an embodiment, the second spacing is defined as a distance between a bottom edge of the first through hole located above each of the multiple first contact electrodes and an upper surface edge of each of the multiple current blocking layers located below each of the multiple first contact electrodes.

In an embodiment, the second spacing includes a third sub-spacing and a fourth sub-spacing, the third sub-spacing is greater than the fourth sub-spacing, and the first contact electrode with the fourth sub-spacing is closer to an edge of the light-emitting diode than the first contact electrode with the third sub-spacing.

In an embodiment, the second spacing includes a third sub-spacing and a fourth sub-spacing, and the third sub-spacing is greater than the fourth sub-spacing. The light-emitting diode further includes multiple second contact electrodes spaced apart above the first semiconductor layer and electrically connected to the first semiconductor layer; the multiple first contact electrodes are distributed both between the multiple second contact electrodes and in a periphery of the multiple second contact electrodes; at least one of the multiple first contact electrodes located between adjacent two of the multiple second contact electrodes has the third sub-spacing; and at least one of the multiple first contact electrodes located at the periphery of the multiple second contact electrodes and closest to an edge of the light-emitting diode has the fourth sub-spacing.

In an embodiment, a difference between the third sub-spacing and the fourth sub-spacing is in a range of 1-5 micrometers.

By limiting the second spacing in the above embodiments, the current distribution and brightness uniformity of the light-emitting diode can be further optimized, and the EOS capability of the light-emitting diode can be improved.

In an embodiment, the light-emitting diode further includes multiple second contact electrodes staggered and spaced above the first semiconductor layer and electrically connected to the first semiconductor layer; and the multiple first contact electrodes are evenly distributed around each of the multiple second contact electrodes.

In an embodiment, the insulating layer further is defined with a second through hole exposing a part of a surface of each of the multiple second contact electrodes, a minimum distance between each of the multiple second contact electrodes and the second through hole is defined as a third spacing, and the third spacing is smaller than the first spacing, so as to effectively reduce the light-emitting loss caused by electrode coverage and improve the brightness of the light-emitting diode.

In an embodiment, the light-emitting diode further includes a current spreading layer, a first connection electrode and a second connection electrode. The current spreading layer is located between the first contact electrode and the second semiconductor layer. The first connection electrode is located on the insulating layer and is electrically connected to multiple second contact electrodes. The second connection electrode is located on the insulating layer and is electrically connected to multiple first contact electrodes.

The disclosure further provides a light-emitting diode, which includes an epitaxial structure, a second contact electrode and an insulating layer. The epitaxial structure includes a first semiconductor layer, an active layer and a second semiconductor layer sequentially stacked in that order. The multiple first contact electrodes are distributed above the second semiconductor layer and electrically connected to the second semiconductor layer. The insulating layer covers at least a part of each of the multiple first contact electrodes and the epitaxial structure. The insulating layer includes a first through hole exposing part of a surface of each of the multiple first contact electrodes. A minimum distance between an edge of the first through hole and an edge of each of the multiple first contact electrodes is defined as a first spacing. The first spacings between the first contact electrodes and the first through holes are equal. At least two first through holes have different minimum diameters.

In an embodiment, the diameters of the first through holes include a third diameter and a fourth diameter, and the third diameter is greater than the fourth diameter. The first through hole with the fourth diameter is closer to the edge of the light-emitting diode than the first through hole with the third diameter.

By limiting the size of the first through hole, the photoelectric characteristics of the light-emitting diode can also be effectively improved.

The disclosure also provides a light-emitting device, which uses the light-emitting diode according to any embodiment to improve the performance of the light-emitting device.

In the following, the technical schemes of the disclosure will be described clearly and completely through various specific embodiments with the attached drawings in the embodiments of the disclosure.

### Embodiment 1

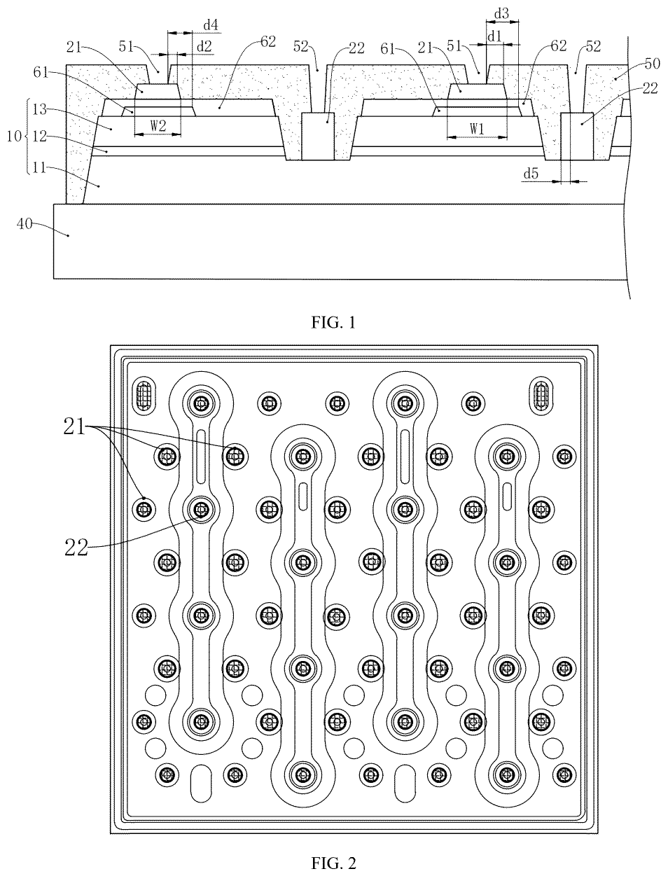

Referring to FIGS. 1-5. FIG. 1 illustrates a cross-sectional view of a light-emitting diode according to an embodiment of the disclosure. The light-emitting diode provided in this embodiment at least includes an epitaxial structure 10, first contact electrodes 21, and an insulating layer 50.

The epitaxial structure 10 is disposed on a substrate 40. The substrate 40 may be an insulating substrate, and specifically, the substrate 40 may be made of a transparent material or a semitransparent material. For example, the substrate 40 is a sapphire substrate or a patterned sapphire substrate. The substrate 40 may also be made of a conductive material or a semiconductor material. For example, the material of the substrate 40 may include at least one of silicon carbide, silicon, magnesium aluminum oxide, magnesium oxide, lithium aluminum oxide, aluminum gallium oxide and gallium nitride.

The epitaxial structure 10 includes a first semiconductor layer 11, an active layer 12, and a second semiconductor layer 13 stacked in sequence on a substrate 40. The first semiconductor layer 11 can be an N-type semiconductor layer, which can provide electrons to the active layer 12 under the action of a power supply. In some embodiments, the first semiconductor layer 11 includes an N-type doped nitride layer. The N-doped nitride layer may include one or more N-type impurities from Group IV elements. The N-type impurities may include one or a combination of silicon (Si), germanium (Ge) and tin (Sn).

The active layer 12 may be a quantum well structure (QW). In some embodiments, the active layer 12 may also be a multiple quantum well structure (MQW). The multiple quantum well structure includes multiple quantum well layers and multiple quantum barrier layers alternately arranged in a repetitive manner, for example, a GaN/AlGaN, InAlGaN/InAlGaN or InGaN/AlGaN multiple quantum well structure. In addition, the composition and thickness of the well layer in the active layer 12 determine the wavelength of the generated light. In order to improve the luminous efficiency of the active layer 12, the depth of quantum wells, the number of layers of paired quantum wells and quantum barriers, the thickness and/or other characteristics can be changed in the active layer 12.

The second semiconductor layer 13 may be a P-type semiconductor layer, and holes may be provided to the active layer 12 under the action of a power supply. In some embodiments, the second semiconductor layer 13 includes a P-type doped nitride layer. The P-type doped nitride layer may include one or more P-type impurities of group II elements. The P-type impurities may include one or a combination of magnesium (Mg), zinc (Zn) and beryllium (Be). The second semiconductor layer 13 may be a single-layer structure or a multi-layer structure with different compositions. In addition, the arrangement of the epitaxial structure 10 is not limited to this, and other functions or types of epitaxial structures can be selected according to actual needs.

Referring to FIG. 1 and FIG. 2, the first contact electrode 21 is located on the epitaxial structure 10 and electrically connected to the second semiconductor layer 13. The first contact electrode 21 has a block structure, and the block structure can be a regular shape such as a cylinder, an elliptical column, a prism or other irregular shapes, which is not limited here. The block structure is dispersed on the surface of the epitaxial structure 10, which can optimize the current expansion capability and also improve the EOS capability.

In some embodiments, the light-emitting diode further includes second contact electrodes 22, which is located on the epitaxial structure 10 and electrically connected to the first semiconductor layer 11. The second contact electrode 22 can be a block structure or a finger structure, which can be designed according to the actual requirements of flip-chip light-emitting diode, and is not limited here. As shown in FIG. 2, in this embodiment, the second contact electrode 22 is a block structure, avoiding the finger structure covering the absorption of brightness.

In some embodiments, referring to FIG. 2, multiple second contact electrodes 22 are distributed on the upper surface of the first semiconductor layer 11 at staggered intervals. The multiple first contact electrodes 21 are evenly distributed around each second contact electrode 22. Specifically, the second contact electrodes 22 are distributed in a staggered manner rather than in a matrix. That is, the staggered distribution means that the second contact electrodes 22 are staggered between adjacent rows or columns, as opposed to the matrix distribution which is arranged in a regular manner and forms neat rows and columns. Through the staggered distribution of the second contact electrodes 22, there can be more space between respective second contact electrodes 22 on the limited surface of the light-emitting diode to distribute more first contact electrodes 21. On the one hand, the increase of the first contact electrodes 21 can ensure that the electrical conductivity and thermal conductivity between the contact electrodes are more uniform on the light-emitting diode, thereby improving the EOS capability of the light-emitting diode. On the other hand, the staggered distribution can also enhance the electric field distribution at the edge of the light-emitting diode, thus improving the brightness of the light-emitting diode.

The second contact electrodes 22 and the first contact electrodes 21 may be metal electrodes, such as one or a combination of any of nickel, gold, titanium, platinum, palladium, chromium, aluminum, tin, indium, copper, iron, tungsten and molybdenum. In some embodiments, the second contact electrodes 22 and the first contact electrodes 21 each include a bottom layer (such as Cr), a reflective layer (such as Al) on the bottom layer and a cap layer (such as Ti, Pt or Ni) on the reflective layer. The bottom layer can ensure the ohmic contact effect between the contact electrode and the epitaxial structure 10, and the thickness of the bottom layer is within 10 nanometers (nm), thus avoiding the influence on the reflectivity.

Further, the insulating layer 50 further includes a second through hole 52 exposing part of the surface of the second contact electrode 22, the minimum distance between the second contact electrode 22 and the second through hole 52 is defined as a third spacing, and the third spacing is smaller than the first spacing. Specifically, as shown in FIG. 1, there is a minimum distance between the second contact electrode 22 and the corresponding second through hole 52 above the second contact electrode 22. When the second through hole 52 is in the shape of a truncated cone, the third spacing is expressed as the distance from the bottom edge of the second through hole 52 to the upper surface edge of the second contact electrode 22. By design that third spacing to be smaller than the first spacing, the luminous loss caused by electrode coverage is reduced, and the brightness of the light-emitting diode is effectively improved.

In some embodiments, a current spreading layer 62 may be arranged between the first contact electrode 21 and the epitaxial structure 10 to further improve the conductivity and enhance the photoelectric characteristics of the light-emitting diode. A current blocking layer 61 may also be arranged below the first contact electrode 21 to suppress the current accumulation phenomenon near the first contact electrode 21 and improve the current spreading performance. Of course, a current spreading layer (not shown in the figure) and a current blocking layer (not shown in the figure) can also be arranged between the second contact electrode 22 and the epitaxial structure 10 to improve the current spreading performance of the light-emitting diode. The specific design can be made reasonably according to the actual needs, which is not limited here.

As an example, the current spreading layer 62 may be at least one of indium tin oxide (ITO) and zinc indium oxide (ZIO), and this embodiment specifically adopts an ITO layer formed by vapor deposition or sputtering process. The current blocking layer 61 may be silicon dioxide (SiO₂), silicon nitride (Si₃N₄), aluminum oxide Al₂O₃, titanium dioxide (TiO₂) or their composite structures.

The insulating layer 50 covers at least part of the first contact electrodes 21 and the epitaxial structure 10, and can extend to cover part of the sidewall of the epitaxial structure 10. Among them, the insulating layer 50 has different effects according to the positions involved. For example, when the insulating layer 50 covers the sidewall of the epitaxial structure 10, it can be used to prevent the first semiconductor layer 11 and the second semiconductor layer 13 from being electrically connected due to the leakage of the conductive material, thus reducing the possibility of short circuit abnormality of the light-emitting diode, but the embodiment of the disclosure is not limited to this. The material of the insulating layer 50 includes a non-conductive material. The non-conductive material is specifically an inorganic material or a dielectric material. The inorganic material may include silica gel. The dielectric material includes electrical insulating materials such as aluminum oxide, silicon nitride, silicon oxide, titanium oxide or magnesium fluoride. For example, the insulating layer 50 may be silicon dioxide, silicon nitride, titanium oxide, tantalum oxide, niobium oxide, barium titanate or a combination thereof, and the combination thereof may be a distributed Bragg reflector (DBR) formed by repeatedly stacking two materials with different refractive indices.

The insulating layer 50 includes a first through hole 51 exposing part of the surface of the first contact electrode 21, so that the first contact electrode 21 can be led out through the first through hole 51. Among them, the first through hole 51 can be a cylindrical hole with a vertical plane side wall, or an inverted frustum hole with an inclined plane or an inclined cambered side wall, and it should be arranged reasonably according to actual needs, for example, the side wall of the first through hole 51 in FIG. 1 is an inclined plane.

In a conventional light-emitting diode, the sizes of each first contact electrode and the corresponding first through hole are set to be equal. However, when the size of the first contact electrode and the first through hole are the same, due to the different layer structures of the light-emitting diode and the position design of the electrode, the current density per unit area is too large and the current distribution is uneven, which leads to the problem of poor EOS capability.

Based on the above, in this embodiment, referring to FIG. 1, the minimum distance between the first through hole 51 and the edge of the first contact electrode 21 is defined as the first spacing, and at least two first contact electrodes 21 have unequal first spacings from the first through hole 51.

Specifically, the current distribution in the light-emitting diode is adjusted by setting the first spacing between a part of the first contact electrodes 21 and the first through holes 51 to be larger and a part of the first contact electrodes 21 and the first through holes 51 to be smaller, so as to reduce the risk of electrode damage caused by local overheating and further improve the overall EOS capability of the light-emitting diode. In some embodiments, the first contact electrode 21 located at the position with relatively strong current distribution has a larger first spacing, and the first contact electrode 21 located at the position with relatively weak current distribution has a smaller first spacing, so that the current can be distributed between the first contact electrodes 21 more reasonably, and the EOS capability of the light-emitting diode can be further improved.

It should be noted that the first spacing refers to the minimum distance between the first through hole 51 and the edge of the first contact electrode 21. In the light-emitting diode, at least part of the first contact electrodes 21 are correspondingly provided with first through holes 51, and the “minimum distance” here refers to the minimum distance between the edge of the first contact electrode 21 and the first through hole 51 above the first contact electrode 21.

Further, the first spacing can also be defined as the distance between the bottom edge of the first through hole 51 and the upper surface edge of the first contact electrode 21. Specifically, as shown in FIG. 1, the first through hole 51 may be in the shape of an inverted circular hole with a wide top and a narrow bottom, or other shapes, and the first contact electrode 21 may have a vertical side wall or an inclined side wall to meet the performance requirements of different light-emitting diodes. Therefore, the first spacing here refers to the minimum distance between the bottom edge of the first through hole 51 and the upper surface edge of the first contact electrode 21.

In some embodiments, the first spacing is in a range of 2-10 micrometers, so as to avoid that the current transmission efficiency is affected by the increase of resistance when the first spacing is too large. At the same time, it avoids the risk associated with an overly small first spacing, such as manufacturing difficulties, electric field concentration, or an overly thin metal barrier layer on the side wall of the first contact electrode 21 due to the smaller first spacing design, which may lead to reliability issues such as moisture or solder paste ingress.

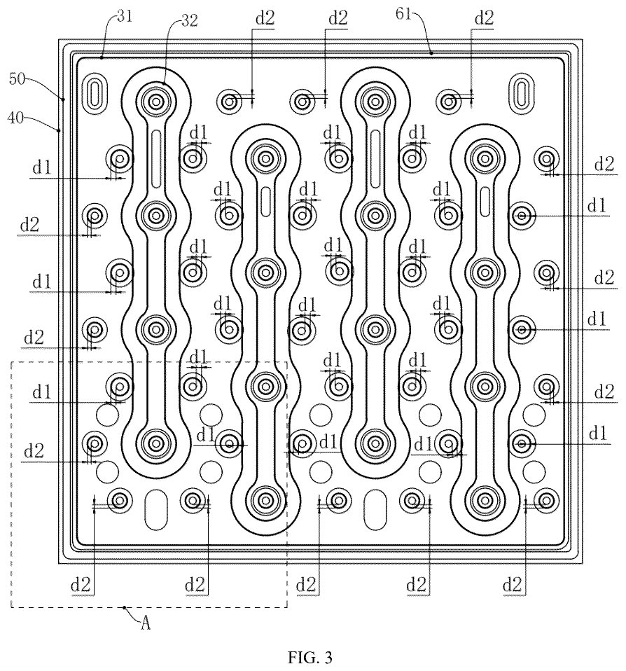

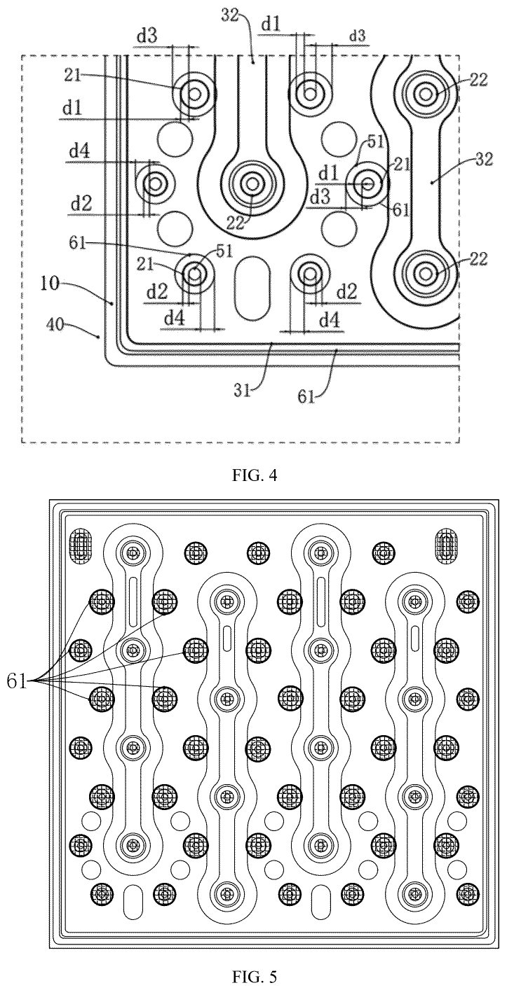

In an alternative embodiment, as shown in FIGS. 3 and 4, the first spacing includes a first sub-spacing d1 and a second sub-spacing d2, and the first sub-spacing d1 is greater than the second sub-spacing D2. The first contact electrode 21 with the second sub-spacing d2 is closer to the edge of the light-emitting diode than the first contact electrode 21 with the first sub-spacing d1.

It should be noted that all the first contact electrodes 21 include two types of first contact electrodes 21, one type of first contact electrodes 21 has a relatively large first spacing, and the other type of first contact electrodes 21 has a relatively small first spacing. The relatively large first spacing is defined as the first sub-spacing d1, and the relatively small first spacing is defined as the second sub-spacing d2. Here, “the first contact electrode 21 with the first sub-spacing d1” refers to a type of first contact electrode 21 in which the minimum distance between the edge of the first contact electrode 21 and the corresponding first through hole 51 is larger than the second sub-spacing d2; and “the first contact electrode 21 with the second sub-spacing d2” refers to a type of first contact electrode 21 in which the minimum distance between the edge of the first contact electrode 21 and the corresponding first through hole 51 is smaller than the first sub-spacing d1.

In practice, the current distribution closer to the edge of the light-emitting diode is relatively weak, and its brightness is relatively low. Therefore, by providing the first contact electrode 21 with the second sub-spacing d2, further decrease in brightness can be avoided. On the contrary, the current distribution facing away from the edge of the light-emitting diode (that is, the center of the light-emitting diode) is relatively strong, making it prone to overcurrent and damage to the light-emitting diode. Therefore, by arranging the first contact electrode 21 with the first sub-spacing d1, the current can be promoted to prevent the occurrence of overcurrent, and then the EOS capability of the light-emitting diode can be improved. In some embodiments, the difference between the first sub-spacing d1 and the second sub-spacing d2 is in a range of 1-5 micrometers. On the premise of ensuring that the first sub-spacing d1 is large to improve the EOS capability, the problems that the second sub-spacing d2 is large due to too small difference value and the first contact electrode 21 at the edge position being relatively large to cause light absorption and brightness reduction are avoided, and at the same time, the EOS capability is prevented from being reduced due to too large difference value and the first contact electrode 21 at the edge position being relatively small.

By limiting the sizes of the first sub-spacing d1 and the second sub-spacing d2, it is possible to reduce the influence of unreasonable size setting of the first sub-spacing d1 and the second sub-spacing d2 on the photoelectric characteristics of the light-emitting diode.

In another alternative embodiment, referring to FIGS. 3 and 4, the light-emitting diode further includes multiple second contact electrodes 22, and the first contact electrodes 21 are distributed both between the second contact electrodes 22 and in a periphery of the second contact electrodes 22, so as to ensure that the electrical and thermal conductivity of the second contact electrodes 22 and the first contact electrodes 21 on the light-emitting diode is more uniform. Specifically, at least one first contact electrode 21 located between adjacent second contact electrodes 22 has a first sub-spacing d1; and at least one first contact electrode 21 located at the periphery of the multiple second contact electrodes 22 and closest to the edge of the light-emitting diode has a second sub-spacing d2. Similarly, the current distribution in the region between adjacent second contact electrodes 22 is stronger, so the first contact electrodes 21 with the first sub-spacing d1 are arranged to prevent overcurrent and improve the EOS capability of the light-emitting diode. However, the current distribution in the region at the periphery of the second contact electrode 22 and close to the light-emitting diode is weak, so the first contact electrodes 21 with the second sub-spacing d2 are arranged to avoid the electrode's absorption of brightness, and further improve the brightness of the light-emitting diode.

In other alternative embodiments, the number of first contact electrodes 21 with the second sub-spacing d2 is smaller than the number of first contact electrodes 21 with the first sub-spacing d1. That is, the number of first contact electrodes 21 with the first sub-spacing d1 is large and located in the region with strong current distribution, while the number of first contact electrodes 21 with the second sub-spacing d2 is small and located in the region with weak current distribution, which can further improve the EOS capability and brightness of the light-emitting diode.

Further, the first spacing refers to the minimum distance between the edge of the first contact electrode 21 and the first through hole 51. In order to make at least two first contact electrodes 21 have unequal first spacings, on the one hand, the sizes and areas of the first contact electrodes 21 can be changed to make the first spacings unequal on the premise that the sizes and areas of the first through holes 51 are equal, and on the other hand, the sizes and areas of the first through holes 51 can be changed to make the first spacings unequal on the premise that the sizes and areas of the first contact electrodes 21 are equal. In addition, the sizes and areas of the first through holes 51 and the first contact electrodes 21 can be changed at the same time, so that at least two corresponding first spacings of the first contact electrodes 21 are not equal. In this embodiment, the cross-sectional areas of the first through holes 51 corresponding to the first contact electrodes 21 are equal on the same horizontal plane, and the cross-sectional areas of at least two first contact electrodes 21 are not equal on the same horizontal plane. That is, by changing the areas of the first contact electrodes 21, the first spacings corresponding to different first contact electrodes 21 are made unequal.

In some embodiments, on the same horizontal plane, the first contact electrode 21 with a smaller cross-sectional area is closer to the edge of the light-emitting diode than the first contact electrode 21 with a larger cross-sectional area. Specifically, setting the first contact electrode 21 with a small cross-sectional area near the edge of the light-emitting diode can reduce the electrode's absorption of brightness and improve the brightness. Setting the first contact electrode 21 with a large cross-sectional area in the region facing away from the edge of the light-emitting diode (that is, the central region of the light-emitting diode) can promote the current to flow and improve the EOS capability.

In some embodiments, the average first spacing between all the first contact electrodes 21 closest to the edge of the light-emitting diode and the first through holes 51 is smaller than the average first spacing between all the first contact electrodes 21 and the first through holes 51 relatively facing away from the edge of the light-emitting diode. Similarly, through this setting, the EOS capability and brightness of the light-emitting diode can be effectively improved.

In an embodiment, the first contact electrodes 21 have diameters, and at least two first contact electrodes 21 have different diameters. By designing the first contact electrodes 21 with different diameters, the current density distribution and optical effect in the light-emitting diode can be further effectively adjusted. Specifically, the diameters of the first contact electrodes 21 include a first diameter W1 and a second diameter W2, the first diameter W1 is larger than the second diameter W2, and the first contact electrode 21 with the second diameter W2 is closer to the edge of the light-emitting diode than the first contact electrode 21 with the first diameter W1. That is, by designing a smaller second diameter W2 for the edge of the light-emitting diode with relatively weak current distribution and a larger first diameter W1 for the center of the light-emitting diode with relatively strong current distribution, the current can be distributed more reasonably on the light-emitting diode, thereby improving the EOS capability. In some embodiments, the first diameter W1 is in a range of 18 to 30 micrometers, and the second diameter W2 is in a range of 15 to 25 micrometers.

By limiting the sizes of the first contact electrode 21 and the first through hole 51 at different positions, the current distribution of the light-emitting diode can be optimized and the EOS capability of the light-emitting diode can be improved.

### Embodiment 2

Referring to FIG. 5, on the basis of the embodiment 1, the light-emitting diode further includes multiple current blocking layers 61 located below the first contact electrode 21. An orthographic projection of the first contact electrode 21 on the epitaxial structure 10 is within a range of an orthographic projection of the current blocking layer 61 on the epitaxial structure 10. Referring to FIGS. 1-5, the minimum distance between the first through hole 51 above the first contact electrode 21 and the edge of the current blocking layer 61 below the first contact electrode 21 is defined as a second spacing. At least two first contact electrodes 21 have unequal second spacings.

In specific implementation, in order to make the second spacings corresponding to at least two first contact electrodes 21 unequal, on the one hand, the sizes and areas of the current blocking layers 61 can be changed to make the second spacings unequal on the premise that the sizes and areas of the first through holes 51 are equal, and on the other hand, the sizes and areas of the first through holes 51 can be changed to make the second spacings unequal on the premise that the sizes and areas of the current blocking layers 61 are equal. In addition, the sizes and areas of the first through holes 51 and the current blocking layers 61 can be changed at the same time, so that at least two corresponding second spacings of the first contact electrodes 21 are not equal. In this embodiment, the cross-sectional areas of the first through holes 51 above the first contact electrodes 21 are the same, and the cross-sectional areas of the current blocking layers 61 below the first contact electrodes 21 are different, so as to realize that at least two corresponding second spacings of the first contact electrodes 21 are not equal.

In this embodiment, by setting the second spacings corresponding to at least two first contact electrodes 21 to be unequal, the current distribution in the light-emitting diode is adjusted, and the EOS capability of the light-emitting diode is further improved. In some embodiments, the first contact electrode 21 located at the position with relatively strong current distribution has a larger second spacing, and the first contact electrode 21 located at the position with relatively weak current distribution has a smaller second spacing. As an example, the second spacing is in a range of 5-15 micrometers.

Further, the second spacing is defined as the distance between the bottom edge of the first through hole 51 located above the first contact electrode 21 and the upper surface edge of the current blocking layer 61 located below the first contact electrode 21. Specifically, the first through hole 51 may be in the shape of an inverted frustum hole with a wide top and a narrow bottom or other shapes to meet the performance requirements of different light-emitting diodes. Therefore, the second spacing here refers to the minimum distance between the bottom edge of the first through hole 51 and the upper surface edge of the current blocking layer 61. For example, in FIG. 1, the first through hole 51 is in the shape of a truncated conc.

In an alternative embodiment, referring to FIG. 5, the second spacing includes a third sub-spacing d3 and a fourth sub-spacing d4, and the third sub-spacing d3 is greater than the fourth sub-spacing D4. The first contact electrode 21 with the fourth sub-spacing d4 is closer to the edge of the light-emitting diode than the first contact electrode 21 with the third sub-spacing d3. In some embodiments, the difference between the third sub-spacing d3 and the fourth sub-spacing d4 is in a range of 1-5 micrometers.

It should be noted that all the first contact electrodes 21 include two types of first contact electrodes 21, one type of first contact electrodes 21 has a relatively large second spacing, and the other type of first contact electrodes 21 has a relatively small second spacing. The relatively large second spacing is defined as the third sub-spacing d3, and the relatively small second spacing is defined as the fourth sub-spacing d4. Here, “the first contact electrode 21 with the third sub-spacing d3” refers to the first contact electrode 21 in which the minimum distance between the first through hole 51 above the first contact electrode 21 and the current blocking layer 61 below the first contact electrode 21 is larger than the fourth sub-spacing d4; “the first contact electrode 21 with the fourth sub-spacing d4” refers to the first contact electrode 21 in which the minimum distance between the first through hole 51 above the first contact electrode 21 and the current blocking layer 61 below the first contact electrode 21 is smaller than the third sub-spacing d3.

In specific implementation, the first contact electrode 21 with the fourth sub-spacing d4 is arranged in the region close to the edge of the light-emitting diode, and the first contact electrode 21 with the third sub-spacing d3 is arranged in the region facing away from the edge of the light-emitting diode, so as to further improve the EOS capability and brightness of the light-emitting diode.

In another alternative embodiment, referring to FIGS. 2 and 4, the light-emitting diode further includes multiple second contact electrodes 22. The first contact electrodes 21 are distributed both between the second contact electrodes 22 and in the periphery of the second contact electrodes 22. At least one first contact electrode 21 located between adjacent second contact electrodes 22 has a third sub-spacing d3; and at least one first contact electrode 21 located at the periphery of the second contact electrodes 22 and closest to the edge of the light-emitting diode has a fourth sub-spacing d4. Through the above settings, the EOS capability and brightness of the light-emitting diode can also be improved.

In other alternative embodiments, the definition of the second spacing may also be that the number of first contact electrodes 21 with the fourth sub-spacing d4 is smaller than the number of first contact electrodes 21 with the third sub-spacing d3. Alternatively, the average second spacing corresponding to the first contact electrode 21 closest to the edge of the light-emitting diode is smaller than the average second spacing corresponding to the first contact electrode 21 relatively facing away from the edge of the light-emitting diode.

It should also be noted that the setting of the second spacing in this embodiment can also be similar to the setting of the first spacing in the above-mentioned embodiment 1. For details, please refer to the setting of the first spacing in the embodiment 1, and this embodiment will not be repeated here.

### Embodiment 3

Different from the embodiment 1 and the embodiment 2, the first spacings between respective first contact electrodes 21 and respective first through holes 51 are equal, and at least two first through holes 51 have different diameters. Because the sizes of the respective first contact electrode and the respective first through holes in the traditional light-emitting diode are designed to be equal, there is a problem of weak EOS ability. Therefore, in this embodiment, the first spacings between respective first contact electrodes 21 and respective first through holes 51 are designed to be equal, and the diameters of the first contact electrodes 21 are controlled to be unequal by adjusting the diameters of the first through holes 51, thereby effectively improving the EOS capability.

Specifically, by setting the diameters of the first through holes 51 corresponding to some of the first contact electrodes 21 to be larger and the diameters of the first through holes 51 corresponding to some of the first contact electrodes 21 to be smaller, the current distribution in the light-emitting diode is adjusted, the risk of electrode damage caused by local overheating is reduced, and the overall EOS capability of the light-emitting diode is further improved.

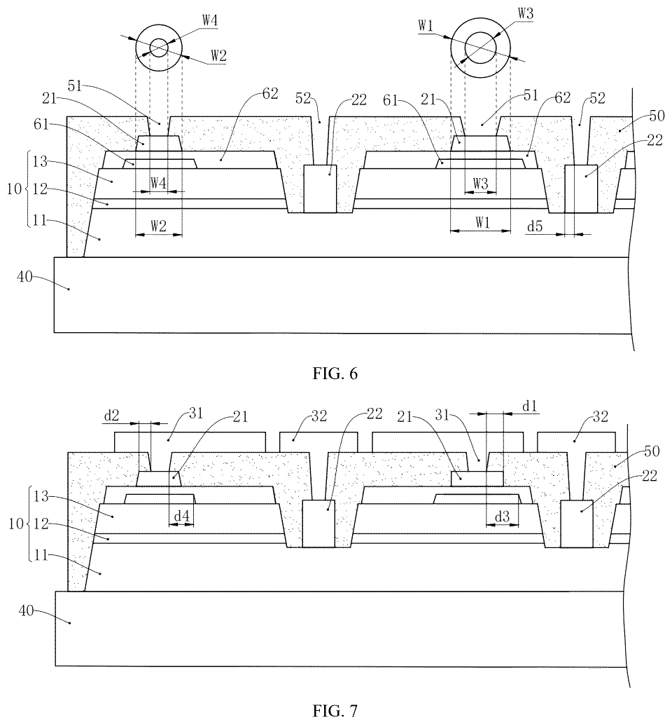

In some embodiments, as shown in FIG. 6, the diameters of the first through holes 51 includes a third diameter W3 and a fourth diameter W4, the third diameter W3 is greater than the fourth diameter W4. The first through hole 51 with the fourth diameter W4 is closer to the edge of the light-emitting diode than the first through hole 51 with the third diameter W3.

It should be noted that there are two types of first through holes 51 in all the first through holes 51. One type of first through holes 51 has a relatively large diameter, and the other type of first through holes 51 has a relatively small diameter. The relatively large diameter is defined as the third diameter W3, and the relatively small diameter is defined as the fourth diameter W4. Here, “the first through hole 51 with the third diameter W3” refers to one type of first through holes 51 whose diameters are larger than the fourth diameter W4, and “the first through hole 51 with the fourth diameter W4” refers to the other type of first through holes 51 whose diameters are smaller than the third diameter W3.

In specific implementation, the current distribution closer to the edge of light-emitting diode is relatively weak, and its brightness is relatively low. Therefore, on the premise that the first spacings are equal, the diameters of the first contact electrodes 21 are controlled to be smaller by setting the first through hole 51 with the fourth diameter W4, and the problem that the brightness is further reduced due to electrode coverage can be avoided. On the contrary, the current distribution facing away from the edge of the light-emitting diode (that is, the center of the light-emitting diode) is relatively strong, and it is easy to cause overcurrent and damage to the light-emitting diode. Therefore, on the premise that the first spacings are equal, the diameters of the first contact electrodes 21 are controlled to be larger by setting the first through hole 51 with the third diameter W3, so as to promote more current to flow, prevent overcurrent and improve the EOS capability of the light-emitting diode.

The sizes of the third diameter W3 and the fourth diameter W4 can be reasonably designed according to actual needs, and are not limited here.

### Embodiment 4

Referring to FIG. 7, on the basis of the embodiment 1, the embodiment 2 and the embodiment 3, the light-emitting diode further includes a first connection electrode 32 and a second connection electrode 31. The first connection electrode 32 is located on the insulating layer 50 and electrically connected to the second contact electrode 22. The second connection electrode 31 is located on the insulating layer 50 and electrically connected to the first contact electrode 21. Specifically, the first connection electrode 32 and the second connection electrode 31 cover the insulating layer 50, and are electrically connected to the second contact electrode 22 and the first contact electrode 21 below through the second through hole 52 and the first through hole 51 filled with the insulating layer 50.

In some embodiments, the first connection electrode 32 and/or the second connection electrode 31 multiple alternately stacked Al/Ti stacks, the number of stacked pairs of the Al/Ti stacks is 4-8, and the number of stacked pairs of this embodiment is specifically 5-7. That is, by increasing the number of stacked pairs of Al/Ti stacks, not only the electrode thickness can be increased, but also the thermal conductivity of the electrode can be optimized, thereby improving the heat dissipation capability of the chip, and the EOS capability can be effectively improved. More specifically, the thickness of the Al layer in the Al/Ti stack is greater than that of the Ti layer. By designing the Al layer thicker, not only can the reflection effect and thermal conductivity be improved and the chip voltage be reduced, but also the ductility and tensile property of Al metal can be used to play a stress buffering role, so as to prevent the electrode from breaking or falling off and increase the reliability.

In other embodiments, the thickness of the first connection electrode 32 and/or the second connection electrode 31 is between 22,500 and 27,500 Angstroms, which can effectively reduce the chip voltage and improve the photoelectric efficiency of the chip.

### Embodiment 5

The disclosure further provides a light-emitting device, and the performance of the light-emitting device can be effectively improved by using the light-emitting diode as described in any of the above embodiments. The specific structure, function and role of the light-emitting diode can refer to the foregoing and will not be described here.

In summary, compared with the related art, the light-emitting diode and the light-emitting device provided by the disclosure can effectively improve the EOS capability of the light-emitting diode through the design of the first contact electrodes and the first through holes, and avoid the risk that the light-emitting diode is prone to structural burn under the overvoltage condition, which may lead to functional failure of the light-emitting diode capability.

In addition, those skilled in the art should understand that although there are many problems in the related art, each embodiment or technical solution of the disclosure can be improved in only one or several aspects, without necessarily resolving all the technical problems listed in the related art or background. Furthermore, those skilled in the art should understand that features not explicitly recited in a claim should not be interpreted as limitations to the scope of that claim.

What is claimed is:

1. A light-emitting diode, comprising:
an epitaxial structure, comprising a first semiconductor layer, an active layer and a second semiconductor layer sequentially stacked in that order;
a plurality of first contact electrodes, distributed above the second semiconductor layer and electrically connected to the second semiconductor layer; and
an insulating layer, covering at least a part of each of the plurality of first contact electrodes and the epitaxial structure; wherein the insulating layer is defined with a first through hole exposing a part of a surface of each of the plurality of first contact electrodes; a minimum distance between an edge of the first through hole and an edge of each of the plurality of first contact electrodes is defined as a first spacing; and at least two of the plurality of first contact electrodes have unequal first spacings relative to the first through hole.

2. The light-emitting diode as claimed in claim 1, wherein the first spacing is in a range of 2 to 10 micrometers.

3. The light-emitting diode as claimed in claim 1, wherein the first spacing is defined as a distance between a bottom edge of the first through hole and an upper surface edge of each of the plurality of first contact electrodes.

4. The light-emitting diode as claimed in claim 1, wherein the first spacing comprises a first sub-spacing and a second sub-spacing, the first sub-spacing is greater than the second sub-spacing, and the first contact electrode with the second sub-spacing is closer to an edge of the light-emitting diode than the first contact electrode with the first sub-spacing.

5. The light-emitting diode as claimed in claim 1, wherein the first spacing includes a first sub-spacing and a second sub-spacing, and the first sub-spacing is greater than the second sub-spacing; and
the light-emitting diode further comprises a plurality of second contact electrodes spaced apart above the first semiconductor layer and electrically connected to the first semiconductor layer; the plurality of first contact electrodes are distributed both between the plurality of second contact electrodes and in a periphery of the plurality of second contact electrodes; at least one of the plurality of first contact electrodes located between adjacent two of the plurality of second contact electrodes has the first sub-spacing; and at least one of the plurality of first contact electrodes located at the periphery of the plurality of second contact electrodes and closest to an edge of the light-emitting diode has the second sub-spacing.

6. The light-emitting diode as claimed in claim 4, wherein a difference between the first sub-spacing and the second sub-spacing is in a range of 1 to 5 micrometers.

7. The light-emitting diode as claimed in claim 5, wherein a difference between the first sub-spacing and the second sub-spacing is in a range of 1 to 5 micrometers.

8. The light-emitting diode as claimed in claim 4, wherein the first contact electrode with the second sub-spacing has smaller quantity than that of the first contact electrode with the first sub-spacing.

9. The light-emitting diode as claimed in claim 5, wherein the first contact electrode with the second sub-spacing has smaller quantity than that of the first contact electrode with the first sub-spacing.

10. The light-emitting diode as claimed in claim 1, wherein cross-sectional areas of the first through hole s respectively corresponding to the plurality of first contact electrodes are equal on a same horizontal plane, and cross-sectional areas of at least two of the plurality of first contact electrodes are unequal on the same horizontal plane.

11. The light-emitting diode as claimed in claim 10, wherein, on the same horizontal plane, a first contact electrode of the at least two of the plurality of first contact electrodes with a smaller cross-sectional area is closer to an edge of the light-emitting diode than another first contact electrode of the at least two of the plurality of first contact electrodes with a larger cross-sectional area.

12. The light-emitting diode as claimed in claim 1, wherein the plurality of first contact electrodes have diameters, and the diameters of at least two of the plurality of first contact electrodes are unequal.

13. The light-emitting diode as claimed in claim 12, wherein the diameters of the plurality of first contact electrodes comprise a first diameter and a second diameter, the first diameter is larger than the second diameter, and the first contact electrode with the second diameter is closer to an edge of the light-emitting diode than the first contact electrode with the first diameter; the first diameter is in a range of 18 to 30 micrometers, and the second diameter is in a range of 15 to 25 micrometers.

14. The light-emitting diode as claimed in claim 1, further comprising a plurality of current blocking layers respectively located below the plurality of first contact electrodes; wherein an orthographic projection of each of the plurality of first contact electrodes on the epitaxial structure is within a range of an orthographic projection of each of the plurality of current blocking layers on the epitaxial structure; a minimum distance between the first through hole located above each of the plurality of first contact electrodes and an edge of each of the plurality of current blocking layers located below each of the plurality of first contact electrodes is defined as a second spacing; and second spacings correspondingly to at least two of the plurality of first contact electrodes are unequal.

15. The light-emitting diode as claimed in claim 14, wherein the second spacing is in a range of 5 to 15 micrometers.

16. The light-emitting diode as claimed in claim 14, wherein the second spacing comprises a third sub-spacing and a fourth sub-spacing, the third sub-spacing is greater than the fourth sub-spacing, and the first contact electrode with the fourth sub-spacing is closer to an edge of the light-emitting diode than the first contact electrode with the third sub-spacing.

17. The light-emitting diode as claimed in claim 14, wherein the second spacing comprises a third sub-spacing and a fourth sub-spacing, and the third sub-spacing is greater than the fourth sub-spacing; and
the light-emitting diode further comprises a plurality of second contact electrodes spaced apart above the first semiconductor layer and electrically connected to the first semiconductor layer; the plurality of first contact electrodes are distributed both between the plurality of second contact electrodes and in a periphery of the plurality of second contact electrodes; at least one of the plurality of first contact electrodes located between adjacent two of the plurality of second contact electrodes has the third sub-spacing; and at least one of the plurality of first contact electrodes located at the periphery of the plurality of second contact electrodes and closest to an edge of the light-emitting diode has the fourth sub-spacing.

18. The light-emitting diode as claimed in claim 1, further comprising a plurality of second contact electrodes staggered and spaced above the first semiconductor layer and electrically connected to the first semiconductor layer; and the plurality of first contact electrodes are evenly distributed around each of the plurality of second contact electrodes.

19. The light-emitting diode as claimed in claim 18, wherein the insulating layer further is defined with a second through hole exposing a part of a surface of each of the plurality of second contact electrodes, a minimum distance between each of the plurality of second contact electrodes and the second through hole is defined as a third spacing, and the third spacing is smaller than the first spacing.

20. A light-emitting device, using the light-emitting diode as claimed in claim 1.
